(19) United States
(12) Patent Application Publication
(10) Pub. No.: US 2026/0293531 A1
(43) Pub. Date: Sep. 24, 2026

(54) MAGNETORESISTANCE EFFECT ELEMENT AND MAGNETIC MEMORY

(71) Applicant: TDK Corporation, Tokyo (JP)

(72) Inventor: Eiji KOMURA, Tokyo (JP)

(73) Assignee: TDK Corporation, Tokyo (JP)

(21) Appl. No.: 19/087,967

(22) Filed: Mar. 24, 2025

(51) Int. Cl. H10N 50/10; G11C 5/08; G11C 11/16; H10N 50/80; H10N 52/80

(52) U.S. Cl. CPC H10N 50/10; G11C 5/08; G11C 11/161; H10N 50/80; H10N 52/80; G11C 11/1673; G11C 11/1675

(57) ABSTRACT

This magnetoresistance effect element has a laminate, a first wiring, a second wiring, a first via wiring, and a second via wiring. The laminate has a spin-orbit torque wiring, a first ferromagnetic layer, a nonmagnetic layer, and a second ferromagnetic layer. The first wiring and the second wiring are connected to the spin-orbit torque wiring. A gap between the first wiring and the second wiring is constant on surfaces where the spin-orbit torque wiring is connected to the first wiring and the second wiring. The first via wiring is connected to the first wiring, and the second via wiring is connected to the second wiring. The gap between the first wiring and the second wiring is shorter than a long axis length of the laminate.

### TECHNICAL FIELD

The present disclosure relates to a magnetoresistance effect element and a magnetic memory.

### BACKGROUND ART

Giant magnetoresistance (GMR) elements constituted of a multilayer film having ferromagnetic layers and a nonmagnetic layer, and tunnel magnetoresistance (TMR) elements using an insulating layer (a tunnel barrier layer, a barrier layer) as a nonmagnetic layer are known as magnetoresistance effect elements. Magnetoresistance effect elements can be applied to magnetic sensors, high-frequency components, magnetic heads, and magnetic random access memories (MRAM).

An MRAM is a storage element in which a magnetoresistance effect element is integrated. An MRAM allows reading and writing of data utilizing characteristics of magnetoresistance effect elements whose resistance varies if magnetization directions of two ferromagnetic layers sandwiching a nonmagnetic layer therebetween in a magnetoresistance effect element vary. For example, the magnetization directions of ferromagnetic layers are controlled utilizing a magnetic field generated by a current. In addition, for example, the magnetization directions of ferromagnetic layers are controlled utilizing a spin transfer torque (STT) generated when a current flows in a lamination direction of a magnetoresistance effect element.

When the magnetization directions of ferromagnetic layers are rewritten utilizing an STT, a current flows in the lamination direction of a magnetoresistance effect element. A writing current may cause deterioration in characteristics of the magnetoresistance effect element.

In recent years, attention has been focused on methods requiring no current to flow in the lamination direction of a magnetoresistance effect element at the time of writing (for example, Patent Document 1). One of the methods is a writing method utilizing a spin-orbit torque (SOT). An SOT is induced due to a spin current generated by a spin-orbit interaction or a Rashba effect in an interface between different kinds of materials. A current for inducing an SOT into a magnetoresistance effect element flows in a direction intersecting the lamination direction of the magnetoresistance effect element. That is, in magnetization rotation using an SOT, there is no need for a current to flow in the lamination direction of the magnetoresistance effect element, and thus an extended lifespan of the magnetoresistance effect element is expected.

### CITATION LIST

### Patent Document

Patent Document 1: Japanese Unexamined Patent Application, First Publication No. 2019-91791

### SUMMARY OF INVENTION

### Technical Problem

Magnetoresistance effect elements are often used in an integrated manner. For example, as in Patent Document 1, magnetoresistance effect elements can be miniaturized by integrally processing a spin-orbit torque wiring and a laminate. On the other hand, as magnetoresistance effect elements become smaller, distances between members constituting magnetoresistance effect elements become shorter. For example, magnetoresistance effect element are sometimes formed on via wirings, and thinning may occur if the distance between the via wirings is short. Thinning is a phenomenon in which unevenness occurs on a polished surface when there is a difference in hardness on the polished surface. Thinning is likely to occur when the width of a part on a polished surface having a different hardness is locally narrow. For example, in Patent Document 1, thinning is curbed by reducing the Vickers hardness difference on a polished surface.

However, as in Patent Document 1, there are restrictions on materials in reducing the Vickers hardness difference on a polished surface. If there are restrictions on materials which can be selected, versatility of the element declines. In addition, if thinning occurs during polishing and the flatness of laminated surfaces of a magnetoresistance effect element is low, characteristics of the magnetoresistance effect element are degraded.

The present disclosure has been made in consideration of the foregoing circumstances, and an object thereof is to provide a magnetoresistance effect element, in which occurrence of thinning is curbed and which is laminated on a flat laminated surface, and a magnetic memory.

### Solution to Problem

In order to resolve the foregoing problems, the present disclosure provides the following means.

A magnetoresistance effect element according to a first aspect has a laminate, a first wiring, a second wiring, a first via wiring, and a second via wiring. The laminate has a spin-orbit torque wiring, a first ferromagnetic layer, a nonmagnetic layer, and a second ferromagnetic layer. The first ferromagnetic layer is located between the spin-orbit torque wiring and the nonmagnetic layer in a lamination direction of the laminate. The nonmagnetic layer is located between the first ferromagnetic layer and the second ferromagnetic layer in the lamination direction of the laminate. The first wiring is connected to the spin-orbit torque wiring. The second wiring is connected to the spin-orbit torque wiring at a position different from a position of the first wiring. A gap between the first wiring and the second wiring is constant on surfaces where the spin-orbit torque wiring is connected to the first wiring and the second wiring. The first via wiring is connected to the first wiring. The second via wiring is connected to the second wiring. The gap between the first wiring and the second wiring is shorter than a long axis length of the laminate.

### Advantageous Effects of Invention

The magnetoresistance effect element and the magnetic memory according to the present disclosure are formed on a flat surface and have excellent magnetic characteristics.

### BRIEF DESCRIPTION OF DRAWINGS

FIG. 1 A schematic circuit diagram of a magnetic memory according to a first embodiment.

FIG. 2 A cross-sectional view of a characteristic portion of the magnetic memory according to the first embodiment.

FIG. 3 A plan view of the magnetic memory according to the first embodiment.

FIG. 4 A cross-sectional view of a magnetoresistance effect element according to the first embodiment.

FIG. 5 Another cross-sectional view of the magnetoresistance effect element according to the first embodiment.

FIG. 6 A plan view of a magnetic memory according to a second embodiment.

### DESCRIPTION OF EMBODIMENTS

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present disclosure is not limited thereto and can be suitably changed and performed within a range in which the effects of the present disclosure are exhibited.

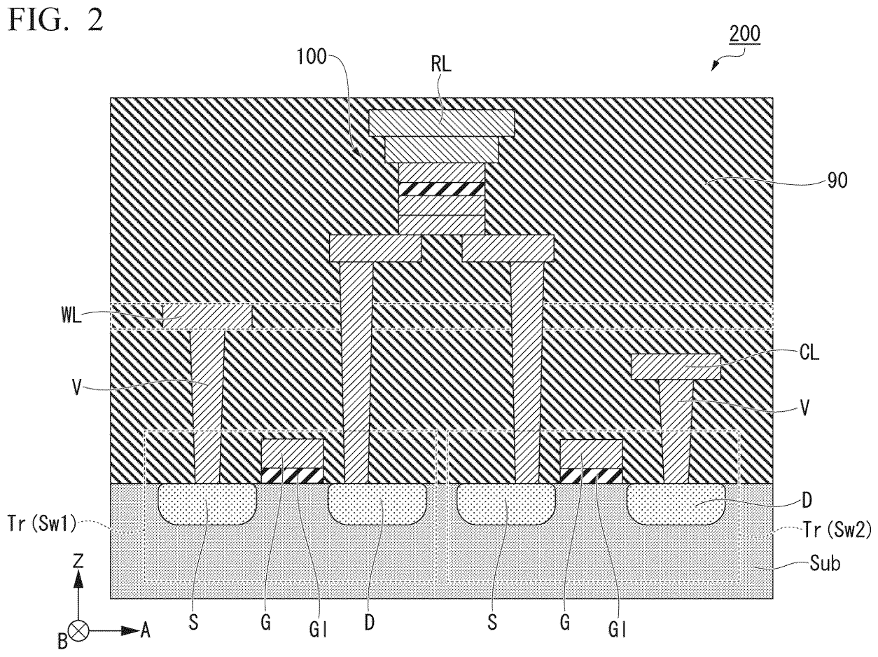

First, directions will be defined. One direction on a surface of a substrate Sub, which will be described below (refer to FIG. 2), will be regarded as an X direction, and a direction orthogonal to the X direction will be regarded as a Y direction. For example, the X direction is a direction along a first straight line connecting a first wiring and a second wiring at the shortest distance. In addition, within an XY plane, a direction along a second straight line connecting a first via wiring and a second via wiring at the shortest distance will be regarded as an A direction, and a direction orthogonal to the A direction will be regarded as a B direction. In addition, a Z direction is a direction orthogonal to the X direction and the Y direction. The Z direction is an example of a lamination direction in which layers are laminated. Hereinafter, a direction from the substrate Sub toward a magnetoresistance effect element will be regarded as the positive Z direction and may be expressed as “upward”. In addition, a direction opposite to the positive Z direction (negative Z direction) may be expressed as “downward”. The upward-downward direction does not necessarily coincide with a direction in which gravity is applied.

In this specification, for example, the expression “extending in the X direction” means that the dimension in the X direction is larger than the smallest dimension of the dimensions in the X direction, the Y direction, and the Z direction. The same applies to the cases of extending in other directions. In addition, in this specification, the term “connection” is not limited to a case of being physically connected. For example, the term “connection” is not limited to a case in which two layers are physically in contact with each other, and it also includes a case in which two layers are connected to each other with another layer sandwiched therebetween. In addition, in this specification, the term “connection” also includes electrical connection.

### First Embodiment

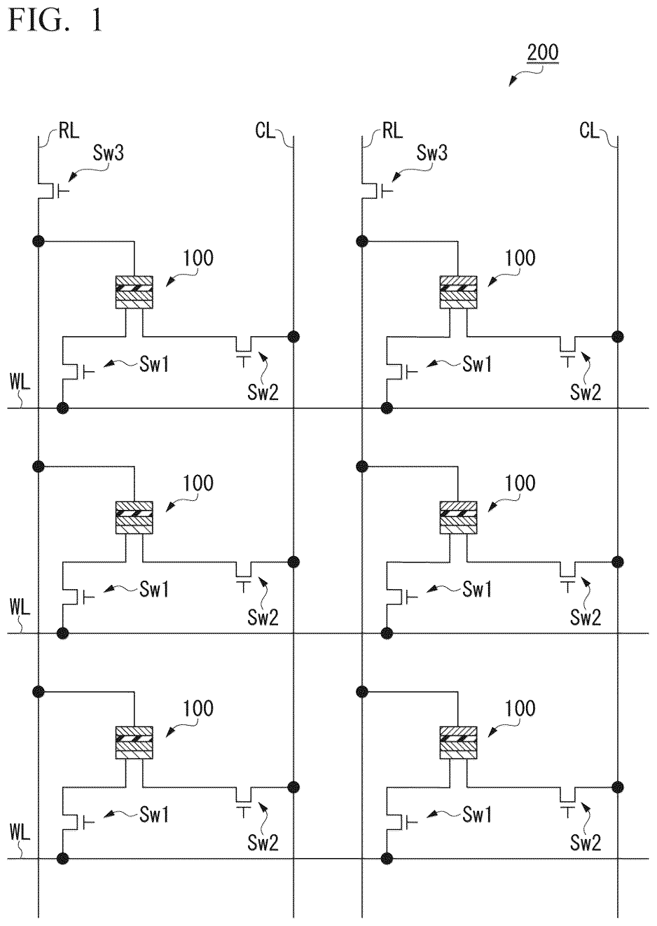

FIG. 1 is a view of a constitution of a magnetic memory 200 according to a first embodiment. The magnetic memory 200 includes a plurality of magnetoresistance effect elements 100, a plurality of writing wirings WL, a plurality of common wirings CL, a plurality of reading wirings RL, a plurality of first switching elements Sw1, a plurality of second switching elements Sw2, and a plurality of third switching elements Sw3.

Each of the writing wirings WL electrically connects a power source to one or more magnetoresistance effect elements 100. Each of the common wirings CL is a wiring used at times of both writing and reading data. Each of the common wirings CL electrically connects a reference potential to one or more magnetoresistance effect elements 100. For example, the reference potential is a ground potential. The common wiring CL may be provided in each of the plurality of magnetoresistance effect elements 100 or may be provided across the plurality of magnetoresistance effect elements 100. Each of the reading wirings RL electrically connects the power source to one or more magnetoresistance effect elements 100. The power source is connected to the magnetic memory 200 when in use.

Each of the magnetoresistance effect elements 100 is connected to the first switching element Sw1, the second switching element Sw2, and the third switching element Sw3. The first switching element Sw1 is connected between the magnetoresistance effect element 100 and the writing wiring WL. The second switching element Sw2 is connected between the magnetoresistance effect element 100 and the common wiring CL. The third switching element Sw3 is connected to the reading wiring RL across the plurality of magnetoresistance effect elements 100.

If a predetermined first switching element Sw1 and a predetermined second switching element Sw2 are turned on, a writing current flows between the writing wiring WL and the common wiring CL connected to a predetermined magnetoresistance effect element 100. Due to a writing current flowing therethrough, data is written in the predetermined magnetoresistance effect element 100. If a predetermined second switching element Sw2 and a predetermined third switching element Sw3 are turned on, a reading current flows between the common wiring CL and the reading wiring RL connected to a predetermined magnetoresistance effect element 100. Due to a reading current flowing therethrough, data is read from the predetermined magnetoresistance effect element 100.

The first switching element Sw1, the second switching element Sw2, and the third switching element Sw3 are elements for controlling a flow of a current. For example, the first switching element Sw1, the second switching element Sw2, and the third switching element Sw3 are transistors. For example, the first switching element Sw1, the second switching element Sw2, and the third switching element Sw3 may be elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

The third switching element Sw3 of the magnetic memory 200 shown in FIG. 1 is shared by the magnetoresistance effect element 100 connected to the same reading wiring RL. The third switching element Sw3 may be provided in each of the magnetoresistance effect elements 100. In addition, the third switching element Sw3 may be provided in each of the magnetoresistance effect elements 100, and the first switching element Sw1 or the second switching element Sw2 may be shared by the magnetoresistance effect element 100 connected to the same wiring.

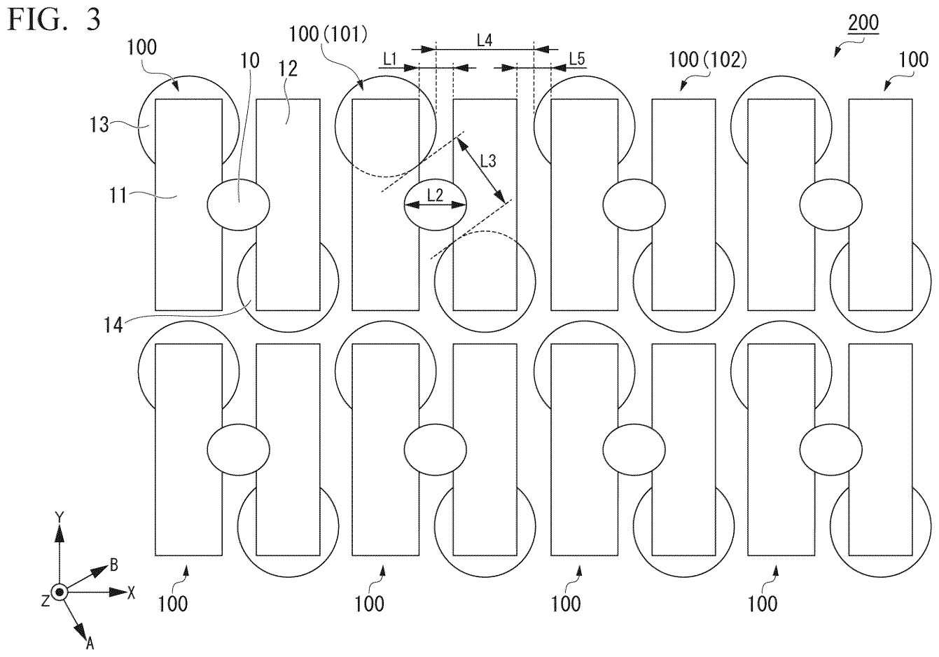

FIG. 2 is a cross-sectional view of a characteristic portion of the magnetic memory 200 according to the first embodiment. FIG. 3 is a plan view of the magnetic memory 200 according to the first embodiment. FIG. 2 is a cross-sectional view of the magnetoresistance effect element 100 cut in the A direction. FIG. 3 is an extracted view of the plurality of magnetoresistance effect elements 100 in the magnetic memory 200, and some constituents are omitted.

The first switching element Sw1 and the second switching element Sw2 shown in FIG. 2 are transistors Tr. The third switching element Sw3 is electrically connected to the reading wiring RL and is located, for example, at a position different from that in the page of FIG. 2. For example, the transistors Tr are field effect transistors each having a gate electrode G, a gate insulating film GI, a source S, and a drain D. The source S and the drain D are prearranged depending on a flowing direction of a current, and the positional relationship between the source S and the drain D may be reversed. For example, the substrate Sub is a semiconductor substrate.

The transistor Tr and the writing wiring WL or the common wiring CL are connected via a via wiring V. For example, the via wiring V extends in the Z direction. The reading wiring RL is connected to the magnetoresistance effect element 100. The via wiring V contains a conductive material.

Areas around the magnetoresistance effect element 100 and the transistors Tr are covered by an insulating layer 90. The insulating layer 90 is an insulating layer providing insulation between wirings of a multilayer wiring or between elements. For example, the insulating layer 90 is made of silicon oxide (SiOₓ), silicon nitride (SiNₓ), silicon carbide (SiC), chromium nitride (CrN), silicon carbonitride (SiCN), silicon oxynitride (SiON), aluminum oxide (Al₂O₃), zirconium oxide (ZrOₓ), magnesium oxide (MgO), aluminum nitride (AlN), or the like.

As shown in FIG. 3, the magnetoresistance effect elements 100 are arrayed in a matrix shape. Each of the magnetoresistance effect elements 100 is a magnetic element utilizing a spin-orbit torque (SOT) and may be referred to as a spin-orbit torque-type magnetoresistance effect element, a spin injection-type magnetoresistance effect element, or a spin current magnetoresistance effect element. The magnetoresistance effect element 100 is an element which records and saves data.

Each of the magnetoresistance effect elements 100 includes a laminate 10, a first wiring 11, a second wiring 12, a first via wiring 13, and a second via wiring 14.

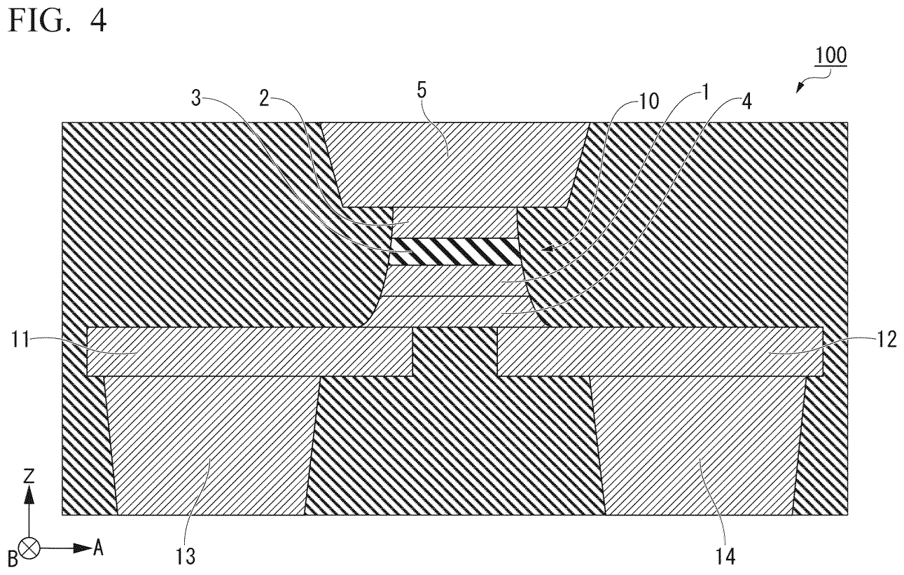

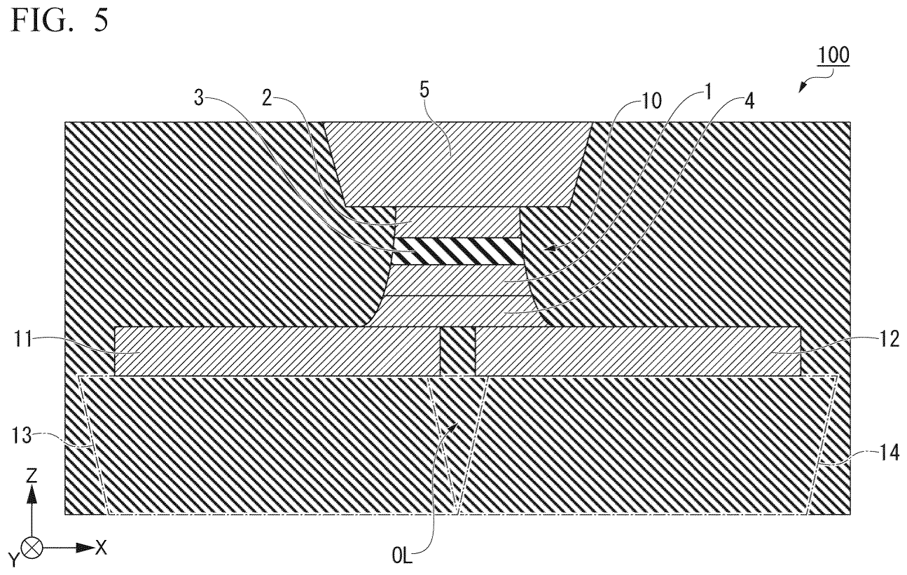

FIG. 4 is a cross-sectional view of the magnetoresistance effect element 100 according to the first embodiment. FIG. 5 is another cross-sectional view of the magnetoresistance effect element 100 according to the first embodiment. FIG. 4 is a cross section of the magnetoresistance effect element 100 cut in the A direction, and FIG. 5 is a cross section of the magnetoresistance effect element 100 cut in the X direction. In FIG. 5, the first via wiring 13 lies in a page depth direction, and the second via wiring 14 lies in a page front direction.

The magnetoresistance effect element 100 records data using a resistance value of the laminate 10 in the Z direction. The resistance value of the laminate 10 in the Z direction varies when a writing current is applied along a spin-orbit torque wiring 4 and spins are injected into a first ferromagnetic layer 1 from the spin-orbit torque wiring 4. The resistance value of the laminate 10 in the Z direction can be read by applying a reading current in the Z direction of the laminate 10.

The laminate 10 has the first ferromagnetic layer 1, a second ferromagnetic layer 2, a nonmagnetic layer 3, and the spin-orbit torque wiring 4. The laminate 10 may have an electrode 5 connecting the reading wiring RL and the second ferromagnetic layer 2. For example, in the laminate 10, the spin-orbit torque wiring 4, the first ferromagnetic layer 1, the nonmagnetic layer 3, and the second ferromagnetic layer 2 are laminated in this order from the side closer to the substrate Sub.

The resistance value of the laminate 10 in the Z direction varies when spins are injected into the first ferromagnetic layer 1 from the spin-orbit torque wiring 4. The resistance value of the laminate 10 in the Z direction varies when the relative angle of magnetization between the first ferromagnetic layer 1 and the second ferromagnetic layer 2 sandwiching the nonmagnetic layer 3 therebetween varies.

For example, the shape of the laminate 10 in a planar view in the z direction is a circular shape, an oval shape, or a quadrangular shape. For example, side surfaces of the laminate 10 are continuous in the Z direction and may be inclined with respect to the Z direction. The side surfaces being continuous in the Z direction means that there is no significant step in an interface between layers, and side surfaces of the layers form a single surface (a planar surface or a curved surface).

The spin-orbit torque wiring 4 generates a spin current due to a spin Hall effect occurring when a current flows and injects spins into the first ferromagnetic layer 1. For example, the spin-orbit torque wiring 4 applies a spin-orbit torque (SOT) to the magnetization of the first ferromagnetic layer 1 by an amount with which the magnetization of the first ferromagnetic layer 1 can be reversed.

The spin Hall effect is a phenomenon in which a spin current is induced in a direction orthogonal to the flowing direction of a current based on a spin-orbit interaction when a current flows. The spin Hall effect is in common with a normal Hall effect in that kinetic (moving) charge (electrons) can bend the kinetic (moving) direction. The normal Hall effect causes the kinetic direction of kinetic charged particles in a magnetic field to bend by means of a Lorentz force. In contrast, the spin Hall effect causes the moving direction of spins to bend simply by means of moving electrons (flowing currents) even if there is no magnetic field.

For example, if a current flows in the spin-orbit torque wiring 4, first spins polarized in one direction and second spins polarized in a direction opposite to that of the first spins individually bend due to the spin Hall effect in a direction orthogonal to the flowing direction of the current. For example, the first spins polarized in the negative B direction bend in the positive Z direction from the A direction that is the traveling direction thereof, and the second spins polarized in the positive B direction bend in the negative Z direction from the A direction that is the traveling direction thereof.

In a nonmagnetic body (a material that is not a ferromagnetic body), the number of electrons in the first spins and the number of electrons in the second spins generated due to the spin Hall effect are the same. That is, the number of electrons in the first spins toward the positive Z direction and the number of electrons in the second spins toward the negative Z direction are the same. The first spins and the second spins flow in directions in which an uneven distribution of the spins is eliminated. Since flows of charge are offset each other in movement of the first spins and the second spins in the Z direction, the current amount becomes zero. A spin current accompanying no current is particularly referred to as a pure spin current.

When a flow of electrons in the first spins is expressed as J_{↑}, a flow of electrons in the second spins is expressed as J_{↓}, and a spin current is expressed as J_{S}, these are defined as J_{S}=J_{↑}−J_{↓}. The spin current J_{S} is generated in the Z direction. The first spins are injected into the first ferromagnetic layer 1 from the spin-orbit torque wiring 4.

For example, the thickness of the spin-orbit torque wiring 4 is 2 nm or larger. For example, the thickness of the spin-orbit torque wiring 4 may be 20 nm or smaller.

The spin-orbit torque wiring 4 contains any of a metal, an alloy, an intermetallic compound, a metal boride, a metal carbide, a metal silicide, a metal phosphide, and a metal nitride having a function of generating a spin current.

For example, the spin-orbit torque wiring 4 contains any one selected from the group consisting of a heavy metal whose atomic number is 39 or larger, a metal oxide, a metal nitride, a metal oxynitride, and a topological insulator. In addition, the spin-orbit torque wiring 4 may contain a magnetic material.

For example, the spin-orbit torque wiring 4 contains a nonmagnetic heavy metal as a main component. A heavy metal means a metal having a specific gravity equal to or greater than that of yttrium (Y). For example, a nonmagnetic heavy metal is a nonmagnetic metal having d electrons or f electrons in its outermost shell and having a large atomic number (atomic number 39 or larger). In a nonmagnetic heavy metal, a spin-orbit interaction stronger than those in other metals occurs. A spin Hall effect occurs due to a spin-orbit interaction, and spins are likely to be unevenly distributed inside the spin-orbit torque wiring 4 so that the spin current J_{S} is likely to be generated.

For example, the first ferromagnetic layer 1 comes into contact with the spin-orbit torque wiring 4 and is laminated on the spin-orbit torque wiring 4.

The first ferromagnetic layer 1 is located between the spin-orbit torque wiring 4 and the nonmagnetic layer 3 in the Z direction. The first ferromagnetic layer 1 is closer to the spin-orbit torque wiring 4 than the second ferromagnetic layer 2. Spins are injected into the first ferromagnetic layer 1 from the spin-orbit torque wiring 4. The magnetization of the first ferromagnetic layer 1 receives a spin-orbit torque (SOT) due to injected spins so that an orientation direction thereof varies. The first ferromagnetic layer 1 is sometimes referred to as a magnetization free layer.

The first ferromagnetic layer 1 contains a ferromagnetic body. For example, the ferromagnetic body is a metal selected from the group consisting of Cr, Mn, Co, Fe, and Ni; an alloy containing one or more kinds of these metals; an alloy containing at least one or more kinds of elements of these metals, B, C, and N; or the like. For example, the ferromagnetic body is an alloy of Co—Fe, Co—Fe—B, Ni—Fe, or Co—Ho; a Sm—Fe alloy; a Fe—Pt alloy; a Co—Pt alloy; or a CoCrPt alloy.

The first ferromagnetic layer 1 may contain a Heusler alloy. The Heusler alloy contains an intermetallic compound having a chemical composition of XYZ or X₂YZ. X represents a transition metal element or a noble metal element of the Co group, the Fe group, the Ni group, or the Cu group on the periodic table. Y represents a transition metal of the Mn group, the V group, the Cr group, or the Ti group, or a kind of an element represented by X. Z represents a typical element of Group III to Group V. For example, the Heusler alloy consists of Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The nonmagnetic layer 3 is sandwiched between the first ferromagnetic layer 1 and the second ferromagnetic layer 2 in the Z direction.

The nonmagnetic layer 3 contains a nonmagnetic body. When the nonmagnetic layer 3 is an insulator (when it is a tunnel barrier layer), for example, Al₂O₃, SiO₂, MgO, MgAl₂O₄, or the like can be used as a material thereof. In addition to these, a material or the like in which a part of Al, Si, or Mg is replaced with Zn, Be, or the like can also be used for the nonmagnetic layer 3. Among these, MgO and MgAl₂O₄ are materials which can realize coherent tunneling. When the nonmagnetic layer 3 is made of a metal, Cu, Au, Ag, or the like can be used as a material thereof. Moreover, when the nonmagnetic layer 3 is constituted of a semiconductor, Si, Ge, CuInSe₂, CuGaSe₂, Cu(In, Ga)Se₂, or the like can be used as a material thereof.

The second ferromagnetic layer 2 is located at a position farther from the spin-orbit torque wiring 4 than the first ferromagnetic layer 1. The orientation direction of the magnetization of the second ferromagnetic layer 2 is less likely to vary than that of the magnetization of the first ferromagnetic layer 1 when a predetermined external force is applied thereto. The second ferromagnetic layer 2 is referred to as a magnetization fixed layer or a magnetization reference layer.

The second ferromagnetic layer 2 contains a ferromagnetic body. A material similar to that of the first ferromagnetic layer 1 can be used for the second ferromagnetic layer 2.

The laminate 10 may have a layer other than the first ferromagnetic layer 1, the second ferromagnetic layer 2, the nonmagnetic layer 3, and the spin-orbit torque wiring. For example, the laminate 10 may have a cap layer on its top surface.

The first wiring 11 is connected to the spin-orbit torque wiring 4 of the laminate 10. For example, the first wiring 11 is connected to a first end of the spin-orbit torque wiring 4.

The second wiring 12 is connected to the spin-orbit torque wiring 4 of the laminate 10. The second wiring 12 is connected to the spin-orbit torque wiring 4 at a position different from that of the first wiring 11. For example, the second wiring 12 is connected to a second end of the spin-orbit torque wiring 4.

As shown in FIG. 3, for example, each of the first wiring 11 and the second wiring 12 is a wiring extending in the Y direction. For example, the first wiring 11 and the second wiring 12 are arranged substantially in parallel in the X direction. A gap L1 between the first wiring 11 and the second wiring 12 is constant on surfaces where the spin-orbit torque wiring 4 is connected to the first wiring 11 and the second wiring 12. The surfaces where the spin-orbit torque wiring 4 is connected to the first wiring 11 and the second wiring 12 are laminated surfaces on which the laminate 10 is laminated at the time of manufacturing. The gap L1 being constant means that a deviation of each of measurement values with respect to the average value of the gap L1 measured at five different points in the Y direction is 10% or smaller.

The gap L1 is shorter than a long axis length L2 of the laminate 10. For example, the length of the gap L1 is 3 nm to 50 nm. For example, the long axis length L2 of the laminate 10 is 10 nm to 80 nm. Since the gap L1 is constant, even when the gap L1 is narrow, occurrence of thinning can be curbed.

As shown in FIG. 3, when a plurality of magnetoresistance effect elements 100 are integrated, the first wiring 11 and the second wiring 12 are alternately arrayed in the X direction with a constant gap therebetween. In the Y direction as well, the first wirings 11 or the second wirings 12 may be arrayed with a constant gap therebetween. The first wiring 11 and the second wiring 12 in each of the magnetoresistance effect elements 100 exhibit a line-and-space pattern.

For example, adjacent elements of the plurality of magnetoresistance effect elements 100 will be regarded as a first magnetoresistance effect element 101 and a second magnetoresistance effect element 102. A gap L5 between the second wiring 12 of the first magnetoresistance effect element 101 and the first wiring 11 of the second magnetoresistance effect element 102 may be 0.9 times to 1.1 times the gap L1 between the first wiring 11 and the second wiring 12 of the first magnetoresistance effect element 101. If the gap L1 and the gap L5 are substantially constant, it is easy to curb occurrence of thinning when a plurality of magnetoresistance effect elements 100 are collectively formed.

The first wiring 11 and the second wiring 12 are made of a conductive material. For example, it is preferable that the first wiring 11 and the second wiring 12 have better conductivity than the spin-orbit torque wiring 4. For example, the first wiring 11 and the second wiring 12 are made of Cu, Al, Ag, or the like.

The first via wiring 13 is connected to the first wiring 11. The second via wiring 14 is connected to the second wiring 12. Each of the first via wiring 13 and the second via wiring 14 is a through wiring extending in the Z direction.

Each of the first via wiring 13 and the second via wiring 14 is located at a position shifted in the Y direction with respect to the laminate 10. In a planar view in the Z direction, the second straight line connecting the first via wiring 13 and the second via wiring 14 at the shortest distance intersects the first straight line connecting the first wiring 11 and the second wiring 12 at the shortest distance.

For example, a shortest distance L3 between the first via wiring 13 and the second via wiring 14 is longer than the gap L1 between the first wiring 11 and the second wiring 12 and is longer than the long axis length L2 of the laminate 10.

As shown in FIG. 3, when a plurality of magnetoresistance effect elements 100 are integrated, the first via wiring 13 and the second via wiring 14 are arrayed in a zigzag manner.

For example, a shortest distance L4 between the first via wiring 13 of the first magnetoresistance effect element 101 and the first via wiring 13 of the second magnetoresistance effect element 102 may be 0.9 times to 1.1 times the shortest distance L3 between the first via wiring 13 and the second via wiring 14 of the first magnetoresistance effect element 101. If the shortest distance L3 and the shortest distance L4 are substantially constant, the via wirings are disposed in a hexagonal close-packed structure so that the magnetoresistance effect elements can be integrated with a high density.

In addition, as shown in FIG. 5, when the magnetoresistance effect element 100 is viewed in the Y direction, the first via wiring 13 and the second via wiring 14 may overlap each other in at least a part. An overlapping portion OL where the first via wiring 13 and the second via wiring 14 overlap each other when viewed in the Y direction can be realized by locating the first via wiring 13 and the second via wiring 14 at positions shifted in the Y direction with respect to the laminate 10. This is because if the overlapping portion OL is formed within the same surface, a writing current will leak through the overlapping portion OL. A large current can flow in the magnetoresistance effect element 100 by making the first via wiring 13 and the second via wiring 14 thicker.

The first via wiring 13 and the second via wiring 14 are made of a conductive material. For example, it is preferable that the first via wiring 13 and the second via wiring 14 have better conductivity than the spin-orbit torque wiring 4. For example, the first via wiring 13 and the second via wiring 14 are made of Cu, Al, Ag, or the like.

Next, a method for manufacturing the magnetoresistance effect element 100 will be described. The magnetoresistance effect element 100 can be produced by laminating layers and processing layers repeatedly. The layers can be laminated using a sputtering method, a chemical vapor deposition (CVD) method, an electron beam evaporation method (EB evaporation method), an atom laser deposition (ALD) method, or the like. For example, the layers can be processed using photolithography or the like.

First, a part of the insulating layer 90 is formed such that the transistors Tr are covered. In addition, the first via wiring 13 and the second via wiring 14 are formed by forming opening portions in the insulating layer 90 and filling the insides of the opening portions with conductors.

The writing wirings WL and the common wirings CL can be formed by laminating the insulating layer 90 to a predetermined thickness, then forming grooves in the insulating layer 90, and filling the grooves with conductors.

For example, surfaces of the insulating layer 90, the first via wiring 13 and the second via wiring 14 are subjected to chemical mechanical polishing (CMP). The shortest distance L3 between the first via wiring 13 and the second via wiring 14 is longer than the long axis length L2 of the laminate 10 so that a sufficient distance is secured. For this reason, compared to when the shortest distance L3 is shorter than the long axis length L2, thinning is less likely to occur when the surfaces are polished.

Next, the first wiring 11 is formed at a position overlapping the first via wiring 13, and the second wiring 12 is formed at a position overlapping the second via wiring 14. For example, after a conductive layer is formed, the conductive layer is processed into shapes of the first wiring 11 and the second wiring 12 so that they can be formed at the same time. Next, the insulating layer 90 is formed such that the first wiring 11 and the second wiring 12 are covered.

Further, the part of the insulating layer 90 is removed until the first wiring 11 and the second wiring 12 are exposed. For example, the surfaces of the insulating layer 90, the first wiring 11, and the second wiring 12 are planarized through chemical mechanical polishing (CMP). The gap L1 between the first wiring 11 and the second wiring 12 is constant. Since there is no spot between the first wiring 11 and the second wiring 12 where the gap therebetween varies locally, occurrence of thinning can be curbed by performing CMP under conditions according to this gap L1.

The laminate 10 is formed on a flat surface which has been planarized. The laminate 10 can be obtained by laminating layers and processing them into a predetermined shape. The side surfaces of the laminate 10 become continuous by processing the spin-orbit torque wiring 4, the first ferromagnetic layer 1, the nonmagnetic layer 3, and the second ferromagnetic layer 2 together. Further, after the electrode 5 is formed, areas around the laminate 10 are covered with the insulating layer 90, thereby obtaining the magnetoresistance effect element 100 according to the first embodiment.

In the magnetoresistance effect element 100 according to the first embodiment, it is possible to curb distortion due to thinning on the laminated surface on which the laminate 10 is laminated. Since the laminate 10 is formed on a flat surface, the magnetic characteristics of the magnetoresistance effect element 100 are enhanced. For example, the magnetoresistance effect element 100 according to the first embodiment has a large MR ratio and is capable of stably recording data.

### Second Embodiment

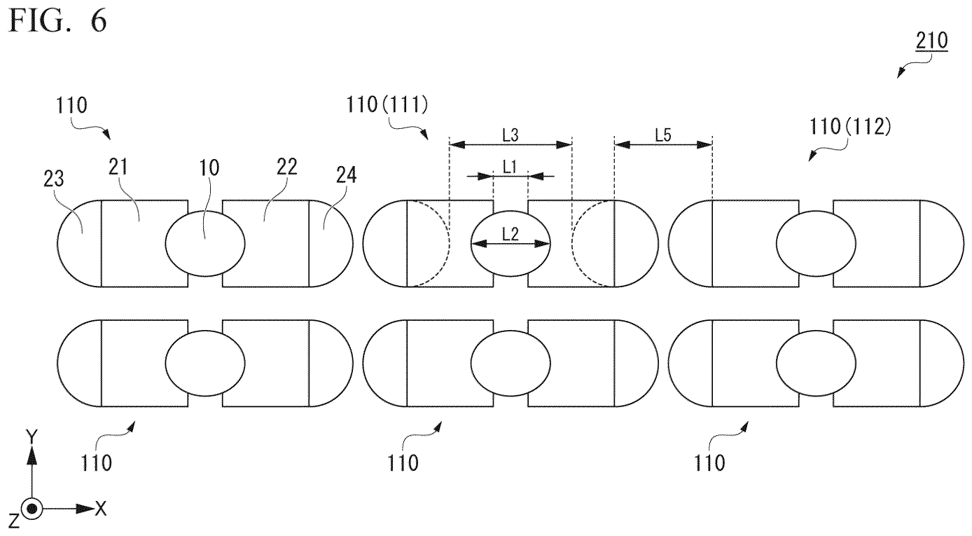

FIG. 6 is a plan view of a magnetic memory 210 according to a second embodiment. The magnetic memory 210 according to the second embodiment differs from the magnetic memory 200 according to the first embodiment in shape of a magnetoresistance effect element 110.

Each of the magnetoresistance effect elements 110 includes the laminate 10, a first wiring 21, a second wiring 22, a first via wiring 23, and a second via wiring 24.

The first wiring 21 corresponds to the first wiring 11 according to the first embodiment, and the second wiring 22 corresponds to the second wiring 12 according to the first embodiment.

As shown in FIG. 6, for example, the first wiring 21 and the second wiring 22 are arranged substantially in parallel in the X direction. The gap L1 between the first wiring 21 and the second wiring 22 is constant on surfaces where the spin-orbit torque wiring 4 is connected to the first wiring 21 and the second wiring 22. The gap L1 is shorter than the long axis length L2 of the laminate 10.

As shown in FIG. 6, when a plurality of magnetoresistance effect elements 110 are integrated, the first wiring 21 and the second wiring 22 are alternately arrayed in the X direction with a constant gap therebetween. In the Y direction as well, the first wirings 21 or the second wirings 22 may be arrayed with a constant gap therebetween. The first wiring 21 and the second wiring 22 in each of the magnetoresistance effect elements 110 exhibit a line-and-space pattern.

For example, adjacent elements of the plurality of magnetoresistance effect elements 110 will be regarded as a first magnetoresistance effect element 111 and a second magnetoresistance effect element 112. The gap L5 between the second wiring 22 of the first magnetoresistance effect element 111 and the first wiring 21 of the second magnetoresistance effect element 112 may be 0.9 times to 1.1 times the gap L1 between the first wiring 21 and the second wiring 22 of the first magnetoresistance effect element 111. Although the example shown in FIG. 6 does not satisfy this constitution, the gap L5 can be adjusted through design of the diameters of the via wirings and the distance between the via wirings.

The first via wiring 23 corresponds to the first via wiring 13 according to the first embodiment, the second via wiring 24 corresponds to the second via wiring 14 according to the first embodiment.

The position of each of the first via wiring 23 and the second via wiring 24 coincides with that of the laminate 10 in the Y direction. In the second embodiment, the A direction coincides with the X direction, and the B direction coincides with the Y direction. In a planar view in the Z direction, the second straight line connecting the first via wiring 23 and the second via wiring 24 at the shortest distance has the same straight line shape as the first straight line connecting the first wiring 21 and the second wiring 22 at the shortest distance.

For example, the shortest distance L3 between the first via wiring 23 and the second via wiring 24 is longer than the gap L1 between the first wiring 21 and the second wiring 22 and is longer than the long axis length L2 of the laminate 10.

As shown in FIG. 6, when a plurality of magnetoresistance effect elements 100 are integrated, the first via wiring 23 and the second via wiring 24 are alternately arrayed in the X direction with a constant gap therebetween. In the Y direction as well, the first via wirings 23 or the second via wirings 24 may be arrayed with a constant gap therebetween.

In the magnetoresistance effect element 110 according to the second embodiment, it is possible to curb distortion due to thinning on the laminated surface on which the laminate 10 is laminated. Since the laminate 10 is formed on a flat surface, the magnetic characteristics of the magnetoresistance effect element 110 are enhanced. For example, the magnetoresistance effect element 110 according to the second embodiment has a large MR ratio and is capable of stably recording data.

Hereinabove, some embodiments have been described in detail with reference to the drawings. However, each of the constitutions and combinations thereof are merely examples, and addition, omission, replacement, and other changes of the constitutions can be made within a range not departing from the gist of the present disclosure.

### REFERENCE SIGNS LIST

1 First ferromagnetic layer
2 Second ferromagnetic layer
3 Nonmagnetic layer
4 Spin-orbit torque wiring
5 Electrode
10 Laminate
11, 21 First wiring
12, 22 Second wiring
13, 23 First via wiring
14, 24 Second via wiring
90 Insulating layer
100, 110 Magnetoresistance effect element
101, 111 First magnetoresistance effect element
102, 112 Second magnetoresistance effect element
200, 210 Magnetic memory
L1, L5 Gap
L3, L4 Shortest distance
OL Overlapping portion

What is claimed is:

1. A magnetoresistance effect element comprising:
a laminate;
a first wiring;
a second wiring;
a first via wiring; and
a second via wiring,
wherein the laminate has a spin-orbit torque wiring, a first ferromagnetic layer, a nonmagnetic layer, and a second ferromagnetic layer,
the first ferromagnetic layer is located between the spin-orbit torque wiring and the nonmagnetic layer in a lamination direction of the laminate,
the nonmagnetic layer is located between the first ferromagnetic layer and the second ferromagnetic layer in the lamination direction of the laminate,
the first wiring is connected to the spin-orbit torque wiring,
the second wiring is connected to the spin-orbit torque wiring at a position different from a position of the first wiring,
a gap between the first wiring and the second wiring is constant on surfaces where the spin-orbit torque wiring is connected to the first wiring and the second wiring,
the first via wiring is connected to the first wiring,
the second via wiring is connected to the second wiring, and
the gap between the first wiring and the second wiring is shorter than a long axis length of the laminate.

2. The magnetoresistance effect element according to claim 1,
wherein a shortest distance between the first via wiring and the second via wiring is longer than the gap between the first wiring and the second wiring.

3. The magnetoresistance effect element according to claim 1,
wherein a shortest distance between the first via wiring and the second via wiring is longer than the long axis length of the laminate.

4. The magnetoresistance effect element according to claim 1,
wherein when viewed in the lamination direction, a first straight line connecting the first wiring and the second wiring at the shortest distance intersects a second straight line connecting the first via wiring and the second via wiring at the shortest distance.

5. The magnetoresistance effect element according to claim 1,
wherein when viewed in the lamination direction, the first via wiring and the second via wiring overlap each other in at least a part when viewed in a second direction orthogonal to a first direction in which a first straight line connecting the first wiring and the second wiring at the shortest distance extends.

6. A magnetic memory comprising:
a magnetoresistance effect element including
a laminate;
a first wiring;
a second wiring;
a first via wiring; and
a second via wiring, wherein
the laminate has a spin-orbit torque wiring, a first ferromagnetic layer, a nonmagnetic layer, and a second ferromagnetic layer,
the first ferromagnetic layer is located between the spin-orbit torque wiring and the nonmagnetic layer in a lamination direction of the laminate,
the nonmagnetic layer is located between the first ferromagnetic layer and the second ferromagnetic layer in the lamination direction of the laminate,
the first wiring is connected to the spin-orbit torque wiring,
the second wiring is connected to the spin-orbit torque wiring at a position different from a position of the first wiring,
a gap between the first wiring and the second wiring is constant on surfaces where the spin-orbit torque wiring is connected to the first wiring and the second wiring,
the first via wiring is connected to the first wiring,
the second via wiring is connected to the second wiring, and
the gap between the first wiring and the second wiring is shorter than a long axis length of the laminate.

7. The magnetic memory according to claim 6 comprising:
a plurality of magnetoresistance effect elements,
wherein a first magnetoresistance effect element and a second magnetoresistance effect element adjacent to each other in the plurality of magnetoresistance effect elements are both the magnetoresistance effect element according to claim 6, and
a shortest distance between the first via wiring of the first magnetoresistance effect element and the first via wiring of the second magnetoresistance effect element is 0.9 times to 1.1 times a shortest distance between the first via wiring and the second via wiring of the first magnetoresistance effect element.

8. The magnetic memory according to claim 6 comprising:
a plurality of magnetoresistance effect elements,
wherein a first magnetoresistance effect element and a second magnetoresistance effect element adjacent to each other in the plurality of magnetoresistance effect elements are both the magnetoresistance effect element according to claim 6, and
a gap between the second wiring of the first magnetoresistance effect element and the first wiring of the second magnetoresistance effect element is 0.9 times to 1.1 times a gap between the first wiring and the second wiring of the first magnetoresistance effect element.
